(19) United States
(12) Patent Application Publication
(10) Pub. No.: US 2010/0284132 A1
(43) Pub. Date: Nov. 11, 2010

(54) TOUCH PANEL MODULE AND METHOD OF MAKING THE SAME

(75) Inventors: Sheng-Hung YI, Taichung County (TW); Yen-Chou Chen, Taichung County (TW); Wen-Pao Yang, Taichung County (TW)

Correspondence Address: HAMRE, SCHUMANN, MUELLER & LARSON, P.C., P.O. BOX 2902, MINNEAPOLIS, MN, 55402-0902, US

(73) Assignee: TAIWAN GREEN POINT ENTERPRISES CO., LTD., Taichung County (TW)

(21) Appl. No.: 12/776,151

(22) Filed: May 7, 2010

Related U.S. Application Data
(60) Provisional application No. 61/176,780, filed on May 8, 2009.

(30) Foreign Application Priority Data
Jan. 4, 2010 (TW) 099100016

(51) Int. Cl. H05K 5/00; G06F 3/044; B29C 45/14

(52) U.S. Cl. 361/679.01; 345/174; 264/272.11; 178/18.06

(57) ABSTRACT

A touch panel module includes a capacitive touch panel and a seamless shell body. The capacitive touch panel includes a touch surface actuated by a touch action. The seamless shell body is formed by a molding material, and includes a touch portion which is transparent and a peripheral portion which is integrally formed with the touch portion, wherein the touch portion is molded to the capacitive touch panel. A method of making the touch panel module is also disclosed.

### CROSS-REFERENCE TO RELATED APPLICATION

This application claims priority from U.S. Provisional Patent Application No. 61/176,780, filed on May 8, 2009.

### BACKGROUND OF THE INVENTION

1. Field of the Invention

The invention relates to a touch panel module, and more particularly to a capacitive type touch panel module. The invention also relates to a method of making the touch panel module.

2. Description of the Related Art

A consumer electronics product with a display screen (for example, a mobile phone, a PDA, or the like) is a product necessary for modern people. There is a growing trend for the consumer electronics product which has a reduced size and an enlarged screen and which is multi-functional and easy to operate. Therefore, the keypad of the electronics product is replaced with a touch panel so that the space for the keypad can be saved for enlarging the size of the display screen.

Referring to FIG. 1, a conventional touch panel module 9 includes a touch panel 91, a shell body 92 bonding the touch panel 91, and a transparent glass plate 93 inserted in the shell body 92. However, the touch panel module 9 has the following disadvantages:

1. The shell body 92 is constituted by two different types of materials, i.e., plastic and glass, so there is visibly a seam 95, which is a visible connection joint between these two different types of materials, formed between the shell body 92 and the transparent glass plate 93, such that the appearance and tightness of the conventional touch panel module 9 is unsatisfactory. Furthermore, the properties of moisture resistance, dust resistance, stain resistance, or the like of the conventional touch panel module 9 are inferior due to the formation of the seam 95, and should be improved.

2. Since the shell body 92 and the transparent glass plate 93 are separately made of different materials and are then bonded together using an adhesive, the manufacturing process for bonding the shell body 92 to the transparent glass plate 93 is time-wasting and costly.

3. In order to maintain a certain surface structural strength of the traditional touch panel module 9, the thickness of the transparent glass plate 93 used in the conventional touch panel module 9 has its limitation. Namely, the thinner the transparent glass plate 93 is, the higher will be the risk of yield loss generated during the manufacturing process. Hence, the overall thickness of the conventional touch panel module 9 is limited. Therefore, there is a need to reduce the structural thickness of the touch panel module while minimizing the risk of yield loss during manufacturing.

### SUMMARY OF THE INVENTION

An object of the present invention is to provide a touch panel module which can overcome the aforesaid disadvantages encountered with the aforesaid prior art.

Another object of the present invention is to provide a method of making the touch panel module.

According to one aspect, the touch panel module of the present invention includes a capacitive touch panel and a seamless shell body. The capacitive touch panel includes a touch surface actuated by a touch action. The seamless shell body is formed by singly molding a transparent material, and includes a touch portion which is transparent and a peripheral portion which is integrally and jointlessly formed with the touch portion. The touch portion corresponds to the capacitive touch panel and has a surface directly bonding the touch surface of the capacitive touch panel.

According to another aspect, the method of making a touch panel module of the present invention includes the steps of: a) preparing a capacitive touch panel including a touch surface; b) disposing the capacitive touch panel into a first mold part; c) closing the first mold part with a second mold part so that a molding space is formed between the touch surface of the capacitive touch panel and the second mold part; and d) insert molding a seamless shell body by singly introducing a molding material into the molding space without changing the position of the mold parts, thereby bonding the seamless shell body to the capacitive touch panel.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a sectional view of a conventional touch panel module;

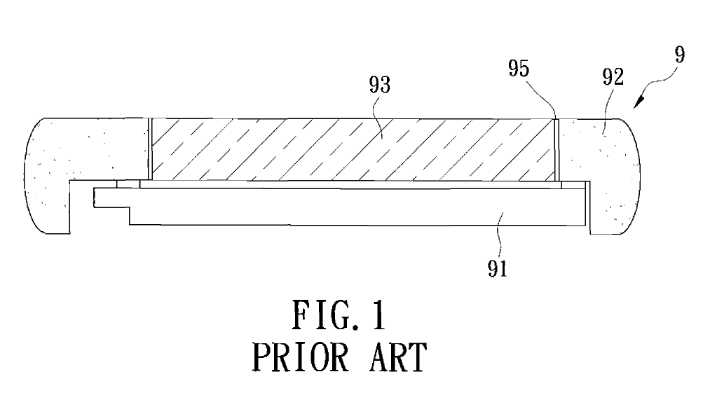

FIG. 2 is a sectional view of a preferred embodiment of a touch panel module according to the present invention;

FIG. 3 is an exploded sectional view of the preferred embodiment of FIG. 2;

FIG. 4 is a top view of the preferred embodiment of the touch panel module according to the present invention;

FIG. 5A is a flow chart of a preferred embodiment of a method of making a touch panel module according to the present invention;

FIG. 5B is a flow chart of one embodiment of a method of making a touch panel module according to the present invention;

FIG. 6A is a schematic sectional view illustrating steps of the preferred embodiment of FIG. 5A; and

FIG. 6B is a schematic sectional view illustrating steps of one embodiment of FIG. 5B.

### DETAILED DESCRIPTION OF THE PREFERRED EMBODIMENTS

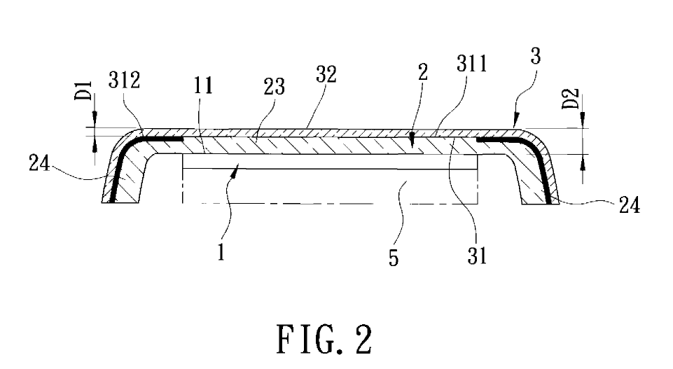

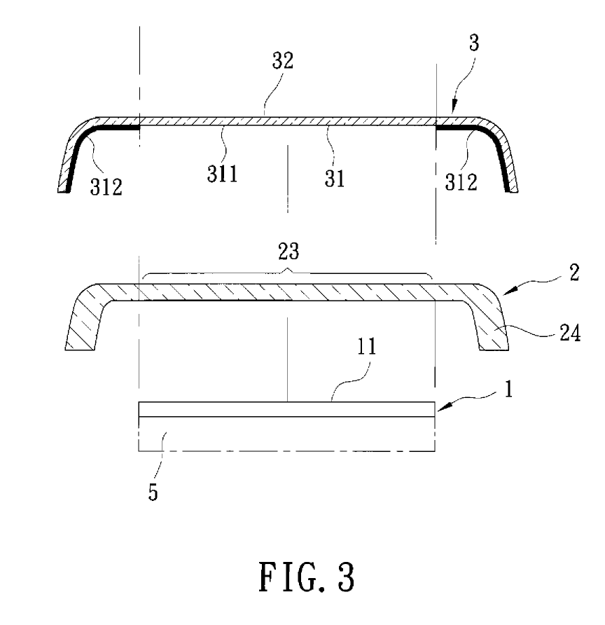

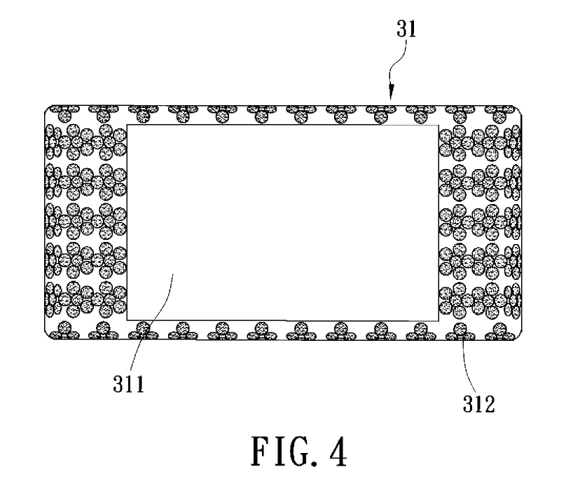

Referring to FIGS. 2, 3 and 4, according to one preferred embodiment of the present invention, the touch panel module includes a capacitive touch panel 1, a seamless shell body 2, and a decorative film layer 3.

The capacitive touch panel 1 is preferably transparent, and includes a touch surface 11 actuated by a touch action. The capacitive touch panel 1 senses the touch action via the touch surface 11 and transforms the touch action into an electric signal. The bottom of the capacitive touch panel 1 further connects to a liquid crystal module (LCM) 5, which is opposite to the touch surface 11.

The seamless shell body 2 is most preferably formed by singly molding a transparent material, which is preferably a transparent polymer material, such as a PC (Polycarbonate), PMMA (Polymethylmethacrylate) or a transparent resin. The seamless shell body 2 includes a touch portion 23 and a peripheral portion 29 formed integrally with the touch portion 23. Specifically in the preferred embodiment, there is no joint visibly or perceptibly found on the seamless shell body 2 as it is a continuous one-piece construction. Therefore, it is visibly jointless between the touch portion 23 and the peripheral portion 24, and this is because the formation of the seamless shell body 2 is performed after singly injecting a molding material into the molding space without changing the position of the mold parts during the molding process. The seamless shell body 2 is moldably affixed or molded onto the touch surface 11 of the capacitive touch panel 1, i.e., such that the shell body 2 directly bonds to the touch surface 11 of the capacitive touch panel 1 as a direct result of the molding process. The touch portion 23 of the seamless shell body 2 is transparent and directly corresponds to the capacitive touch panel 1.

The decorative film layer 3 which is preferably prepared by printing a predetermined pattern on a flexible film has a decorated surface 31 and a non-decorated surface 32 opposite to the decorated surface 31. The decorated surface 31 comprises a non-pattern portion 311 and a pattern portion 312. The non-pattern portion 311 is a transparent area, and corresponds to the touch portion 23 of the seamless shell body 2. The pattern portion 312 preferably corresponds to the peripheral portion 29 of the seamless shell body 2. The aforesaid flexible film is preferably a transparent polymer material, such as PC (Polycarbonate), PET (Polyethylene terephthalate) or the like.

According to some embodiments of the present invention, the thickness of the seamless shell body 2 of the present invention is preferably between 1.0 mm (millimeter) and 1.6 mm (millimeter). The thickness (D1) of the decorative film layer 3 is preferably in a range from 0.075 mm (millimeter) to 0.2 mm (millimeter), and is most preferably around 0.178 mm (millimeter). The total thickness (D2) of the decorative film layer 3 and the seamless shell body 2 is preferably between 1.075 mm (millimeter) and 1.8 mm (millimeter).

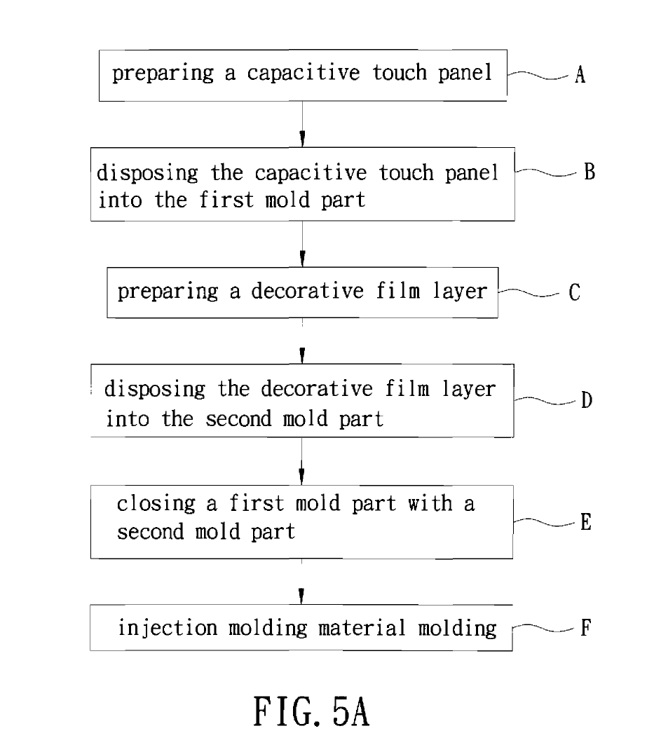

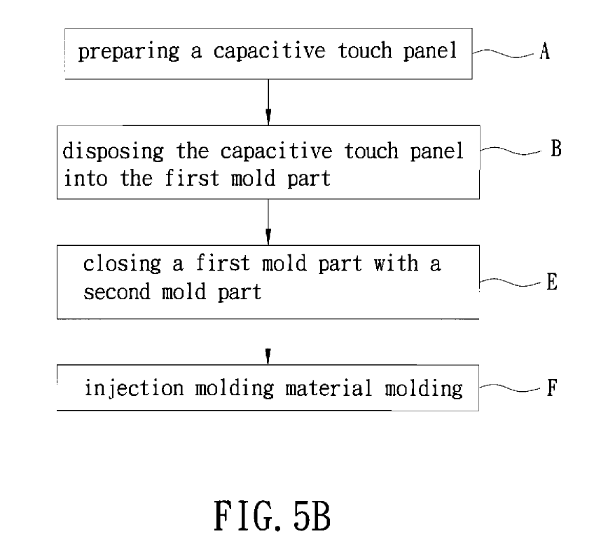

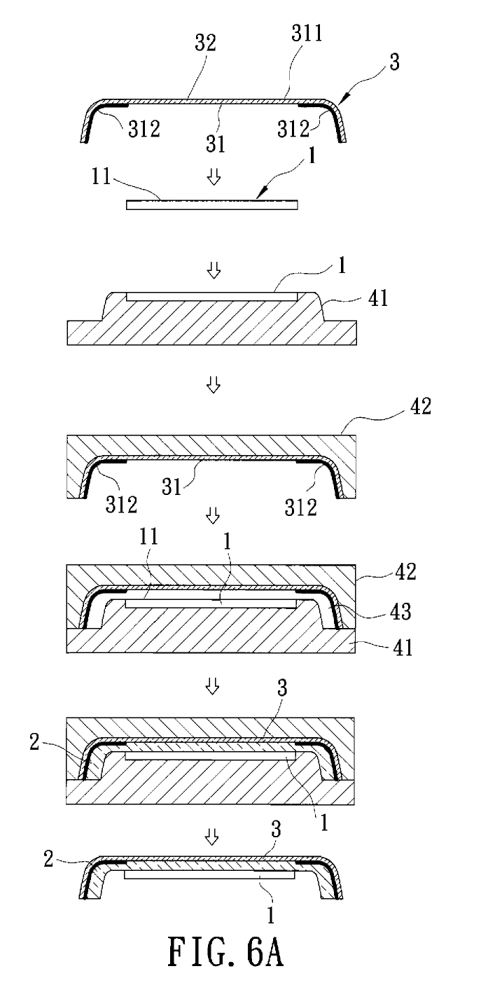

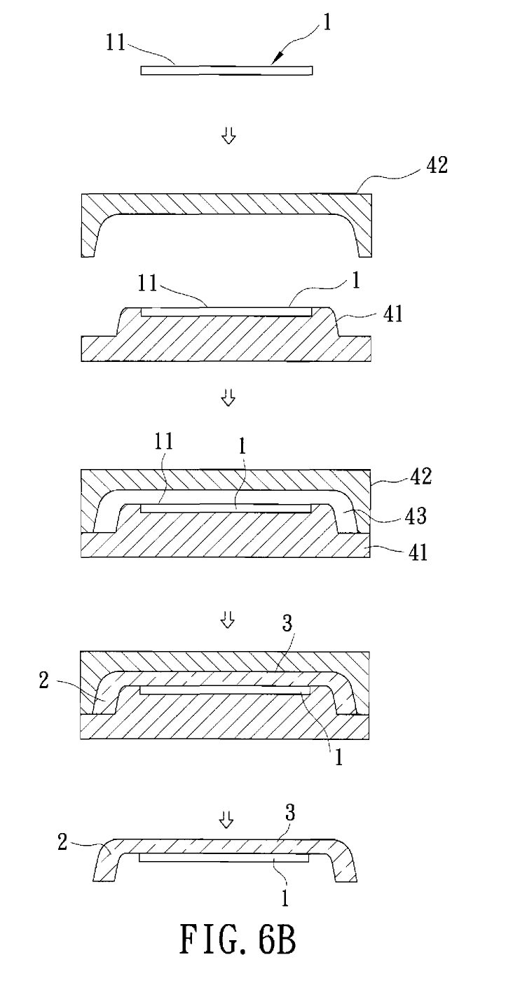

Referring to FIGS. 5A, 5B, 6A and 6B, according to one preferred embodiment of the present invention, a method of making the touch panel module includes the steps of:

A) Preparing a Capacitive Touch Panel:

The aforesaid capacitive touch panel 1 is prepared, which includes the touch surface 11 actuated by a touch action.

B) Disposing the Capacitive Touch Panel:

The aforementioned capacitive touch panel 1 is disposed into a first mold part 41.

C) Preparing a Decorative Film Layer:

The aforesaid decorative film layer 3 is preferably prepared by printing a predetermined pattern on a flexible film having a preferred thickness between 0.075 mm (millimeter) and 0.2 mm (millimeter) to form the decorated surface 31 comprising a non-pattern portion 311 and a pattern portion 312.

D) Disposing the Decorative Film Layer:

The aforementioned decorative film layer 3 having the decorated surface 31 and the non-decorated surface 32 is disposed into a second mold part 42.

E) Closing the First Mold Part with the Second Mold Part:

The first mold part 41 having the capacitive touch panel 1 is closed with the second mold part 42, which is a female mold having a cavity, a molding space being formed between the female mold and the capacitive touch panel 1. More specifically, the decorative film layer 3 is placed in the second mold part 42 so that a specific molding space 43 is formed between the touch surface 11 of the capacitive touch panel 1 and the decorated surface 31 of the decorative film layer 3.

F) Injection Molding:

The seamless shell body 2 is formed by injecting a transparent polymer material, preferably a transparent plastic material, such as PC (Polycarbonate), PMMA (Polymethylmethacrylate), or a transparent resin, into the molding space. Accordingly, the seamless shell body 2 is formed by injecting a transparent polymer molding material without changing mold parts during the molding process, and the seamless shell body 2 is moldably bonded to the capacitive touch panel 1. More specifically, the decorative film layer 3 bonds to the seamless shell body 2 opposite to the capacitive touch panel 1. A product of a touch panel module having a seamless shell body 2 is thus formed. The insert molding process is conducted according to the processing conditions well known in the art.

In view of the aforesaid, the touch panel module of the present invention has the following advantages:

1. Since the shell body 2 is seamless and jointless, the appearance, the moisture resistance, the dust resistance, the stain resistance, and the tightness of the touch panel module of the present invention are improved.

2. Since the touch portion 23 and the peripheral portion 24 of the seamless shell body 2 are integrally formed, the method for making the touch panel module of the present invention is relatively simple and inexpensive as compared to the prior art in which the shell body 92 and the transparent glass plate 93 are separately made of different materials and are then bonded together using an adhesive.

3. Since the seamless shell body 2 is directly formed by the injection molding material, and the interior and exterior of the seamless shell body 2 are directly and individually connected to the capacitive touch panel 1 and the decorative film layer 3, the thickness of the touch portion is successfully and largely reduced compared to the aforesaid prior art structure.

4. Owing to the integral formation of the touch panel module by injection molding, the manufacturing process is reduced and the productivity is increased because the manufacturing process time is reduced accordingly.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

We claim:

1. A touch panel module, comprising:
a capacitive touch panel including a touch surface for actuation by a touch action; and
a molded shell body having a transparent touch portion corresponding to the touch surface, and another portion peripheral to the touch portion and integrally formed therewith in a one-piece construction;
wherein said capacitive touch panel is moldably bonded to the molded shell body such that the touch surface is aligned with the transparent touch portion of the molded shell body.

2. The touch panel module as claimed in claim 1, wherein the molded shell body is seamless, and said touch portion of the molded shell body is formed from a transparent polymer material.

3. The touch panel module as claimed in claim 2, wherein said molded shell body has a thickness between 1.0 mm (millimeter) and 1.6 mm (millimeter).

4. The touch panel module as claimed in claim 2, further comprising a decorative film layer having a decorated surface and a non-decorated surface opposite to said decorated surface, said decorated surface being bonded directly to said molded shell body opposite to said capacitive touch panel.

5. The touch panel module as claimed in claim 4, wherein said decorated surface of said decorative film layer comprises a non-pattern portion that defines the transparent portion and a pattern portion that defines the peripheral portion.

6. The touch panel module as claimed in claim 4, wherein said decorative film layer has a thickness between 0.075 mm (millimeter) and 0.2 mm (millimeter).

7. The touch panel module as claimed in claim 1, wherein said capacitive touch panel is transparent.

8. A method of making a touch panel module, comprising the steps of:
step a) preparing a capacitive touch panel including a touch surface;
step b) disposing the capacitive touch panel into a first mold part;
step c) closing the first mold part with a second mold part so that a molding space is formed between the touch surface of the capacitive touch panel and the second mold part; and
step d) injection molding a seamless shell body by singly introducing a polymer molding material into the molding space without changing mold parts position during this step, thereby bonding the seamless shell body to the capacitive touch panel.

9. The method as claimed in claim 8, wherein the seamless shell body includes a touch portion which is transparent and corresponds to the position of the capacitive touch panel in step d).

10. The method as claimed in claim 8, further comprising a step of disposing a decorative film layer into the second mold part prior to step c), wherein the decorative film layer has a decorated surface and a non-decorated surface opposite to the decorated surface, thereby forming the molding space between the touch surface of the capacitive touch panel and the non-decorated surface of the decorative film layer, and thereby bonding the decorative film layer to the seamless shell body opposite to the capacitive touch panel after step d).

11. The method as claimed in claim 10, wherein the decorative film layer is transparent.

12. The method as claimed in claim 11, further comprising a step of preparing the decorative film layer which comprises a pattern portion and a non-pattern portion on the decorated surface of the decorative film layer, wherein the non-pattern portion corresponds to the touch surface of the capacitive touch panel.
